(19) United States
(12) Patent Application Publication
(10) Pub. No.: US 2014/0176186 A1
(43) Pub. Date: Jun. 26, 2014

(54) GRAPHENE MULTIPLE-VALUED LOGIC DEVICE, OPERATION METHOD THEREOF, AND FABRICATION METHOD THEREOF

(71) Applicant: Gwangju Institute Of Science And Technology, Gwangju (KR)

(72) Inventors: Byoung Hun LEE, Gwangju (KR); Hyeon Jun HWANG, Gwangju (KR); Yoon Ji KIM, Gwangju (KR)

(73) Assignee: GWANGJU INSTITUTE OF SCIENCE AND TECHNOLOGY, Gwangju (KR)

(21) Appl. No.: 14/136,493

(22) Filed: Dec. 20, 2013

(30) Foreign Application Priority Data
Dec. 21, 2012 (KR) 10-2012-0150200

(51) Int. Cl. H01L 29/16; H03K 19/0175; H01L 29/786; H01L 29/66; H01L 29/78

(52) U.S. Cl. CPC H01L 29/1606; H01L 29/66484; H01L 29/7831; H01L 29/78645; H01L 29/66742; H03K 19/017581
USPC 326/38; 257/29; 438/283

(57) ABSTRACT

A graphene multiple-valued logic device and a fabrication method thereof are disclosed. The graphene multiple-valued logic device includes a substrate, a graphene channel layer disposed on the substrate, source and drain electrodes disposed at both ends of the graphene channel layer, respectively, an insulator film formed on the graphene channel layer; and at least two gate electrodes disposed on the insulator film with a predetermined gap defined therebetween. The device allows adjustment of conductivity and resistance of the graphene channel layer depending on a gate voltage, whereby electric current flowing in the device can be variously changed when applied to a multiple-valued logic system.

### CROSS-REFERENCE TO RELATED APPLICATION

This application claims priority to Korean Patent Application No. 10-2012-0150200 filed on 21 Dec. 2012, and all the benefits accruing therefrom under 35 U.S.C. §119, the contents of which is incorporated by reference in its entirety.

### BACKGROUND

1. Technical Field

The present invention relates to a logic device, an operation method thereof and a fabrication method thereof, and more particularly, to a multiple-valued logic device, an operation method thereof and a fabrication method thereof.

2. Description of the Related Art

Generally, a multiple-valued logic system, applied to ultra large scale integration (ULSI) or very large scale integration (VLSI), has a merit of processing more data at once than existing binary logic systems.

A multiple-valued logic system allocates multiple voltage sources and thus needs a circuit configuration capable of processing multiple voltages. Generally, plural devices, such as single electron transistors (SETs), universal literal gates (ULGs), metal oxide semiconductor field effect transistors (MOSFETs), capacitors, and the like, are used to realize a multiple-valued logic system. As a result, the circuit configuration of the system is extremely complicated. Moreover, the use of the plural devices provides a complicated fabrication process and limits integration.

Graphene has a two-dimensional thin film structure in which carbon atoms are arranged in a honeycomb-shaped hexagonal lattice. Since graphene has a two-dimensional shape, graphene can be easily fabricated using a silicon processing technology (CMOS technology). Therefore, electronic devices using graphene are spotlighted as future electronic devices capable of replacing existing electronic devices in the art.

Korean Publication No. 10-2011-0041791 discloses a graphene device. The graphene device includes: a substrate; an embedded gate formed on the substrate; a top oxide film formed on the embedded gate; and a graphene channel and electrodes disposed on the top oxide film.

Depending on voltage applied to the embedded gate, some regions of the graphene channel may become a p-type or an n-type channel. For example, when the number of embedded gates is two, the graphene device may have four types of pp-type, pn-type, np-type and nn-type channels.

However, in the case that the p-type and n-type graphene channels have similar resistance when a specific voltage is applied to the embedded gate, the device has difficulty functioning as a multiple-valued logic device due to small difference in resistance between the channels in the device.

### BRIEF SUMMARY

It is an aspect of the present invention to provide a graphene multiple-valued logic device which enables simplification of a circuit of a logic system and has improved structure and performance, an operation method thereof, and a fabrication method thereof.

In accordance with an aspect of the present invention, a graphene multiple-valued logic device is provided. The graphene multiple-valued logic device includes: a substrate; a graphene channel layer disposed on the substrate; source and drain electrodes disposed at both ends of the graphene channel layer, respectively; an insulator film formed on the graphene channel layer; and at least two gate electrodes disposed on the insulator film with a predetermined gap defined therebetween.

A ground voltage may be applied to a region in the graphene channel layer facing the predetermined gap between the gate electrodes through the substrate.

The graphene channel layer may have one conduction type selected from among p-type, n-type and i-type conductivities in a region facing the gate electrodes depending on voltage applied to the gate electrodes.

The source and drain electrodes may overlap at least one of the gate electrodes.

In accordance with another aspect of the present invention, a method of operating a graphene multiple-valued logic device is provided. The method includes: providing a graphene multiple-valued logic device including a substrate, a graphene channel layer disposed on the substrate, a source and a drain electrodes disposed at both ends of the graphene channel layer, respectively, an insulator film formed on the graphene channel layer on which the source and drain electrodes are disposed, and first and second gate electrodes disposed on the insulator film with a predetermined gap defined therebetween; determining a conduction type of the graphene channel layer by applying a ground voltage to the graphene channel layer disposed between the first and second gate electrodes; forming a conduction type of the graphene channel layer facing the first gate electrode by applying a positive or negative gate voltage to the first gate electrode with reference to the ground voltage; forming a conduction type of the graphene channel layer facing the second gate electrode by applying a positive or negative gate voltage to the second gate electrode with reference to the ground voltage; and calculating total resistance of the graphene channel layer varying with voltage applied to the first and second gate electrodes.

The determining a conduction type of the graphene channel layer may be an operation of applying a back gate voltage to the graphene channel layer using the substrate as a back gate.

Each of a region of the graphene channel layer facing the first gate electrode and a region of the graphene channel layer facing the second gate electrode may have one conduction type selected from among p-type, n-type and i-type conductivities.

In accordance with a further aspect of the present invention, a method of fabricating a graphene multiple-valued logic device is provided. The method includes: forming a graphene channel layer on a substrate; forming source and drain electrodes at both ends of the graphene channel, respectively; forming an insulator film on the graphene channel layer on which the source and drain electrodes are formed; and forming at least two gate electrodes on the insulator film.

The gate electrodes may be disposed to have a predetermined gap therebetween.

The method may further include forming regions each having one conduction type selected from among p-type, n-type and i-type conductivities within the graphine channel layer facing the gate electrodes by applying voltage to the gate electrodes.

According to embodiments of the invention, the multiple-valued logic allows adjustment of conductivity and resistance of the graphene channel layer depending on a gate voltage, whereby electric current flowing in the device can be variously changed when applied to a multiple-valued logic system. In addition, based on a state of the graphene channel layer at a back gate reference voltage, since channels having different conduction types can be formed in the graphene channel layer upon application of gate voltage, a device optimized to realize the multiple-valued logic system can be provided. Further, since a circuit of the multiple-valued logic system can be simplified, the graphene multiple-valued logic device has an advantage of high integration.

### BRIEF DESCRIPTION OF THE DRAWINGS

The above and other aspects, features, and advantages of the present invention will become apparent to those skilled in the art from the detailed description of the following embodiments in conjunction with the accompanying drawings, in which:

FIG. 1 is a sectional view of a graphene multiple-valued logic device according to one embodiment of the present invention;

FIG. 2 shows resistance change of a graphene multiple-valued logic device according to one embodiment of the present invention;

FIG. 3 shows a current-voltage characteristic curve of a graphene channel layer according to one embodiment of the present invention;

FIG. 4 is a sectional view of a graphene multiple-valued logic device according to another embodiment of the present invention; and

FIGS. 5a to 5d show flow diagrams of a method of fabricating a graphene multiple-valued logic device according to one embodiment of the present invention.

### DETAILED DESCRIPTION

Now, exemplary embodiments of the invention will be described in detail with reference to the accompanying drawings. However, it should be understood that the present invention is not limited to the following embodiments and may be embodied in different ways, and includes all equivalents and alternatives within the scope and spirit of the invention.

It will be understood that when an element is referred to as being placed or disposed “on” another element, it can be directly placed or disposed on the other element, or intervening elements may also be present. In addition, expressions of directions such as a top side, an upper (portion), an upper surface and the like as used herein may be understood as meanings such as a bottom side, a lower (portion), a lower surface and the like. That is, expressions of spatial directions should be understood as relative directions, and should not be construed as being limited to absolute directions.

In the drawings, thicknesses of layers and regions may be exaggerated or omitted for clarity. Like components will be denoted by like reference numerals throughout the specification.

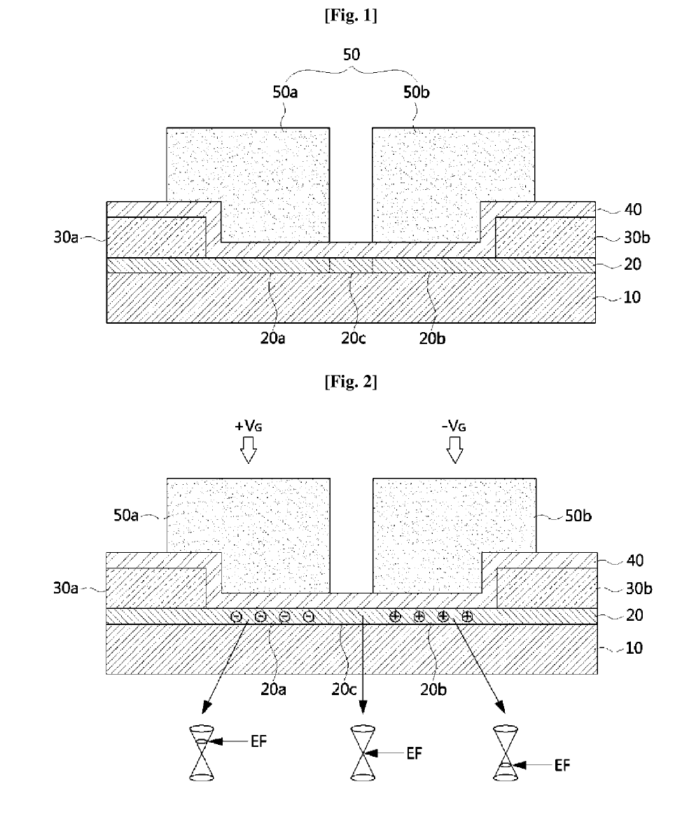

FIG. 1 is a sectional view of a graphene multiple-valued logic device according to one embodiment of the present invention.

Referring to FIG. 1, a substrate 10 may be disposed. The substrate 10 may function as a back gate. In one example, the substrate 10 may be a silicon substrate coated with a silicon oxide film (SiO₂), without being limited thereto.

A graphene channel layer 20 is disposed on the substrate 10. The graphene channel layer 20 may function as a channel through which carriers move. The graphene channel layer 20 may be a layer, the conduction type of which is determined depending on back gate voltage applied thereto. In addition, the graphene channel layer 20 may be a layer, the Fermi energy level of which moves depending on the gate voltage applied thereto. Thus, regions 20a, 20b, 20c of different conduction types may be formed in the graphene channel layer 20 depending on the back gate and gate voltage applied thereto.

Types of carriers moving in the graphene channel layer 20 may vary with polarity of voltage applied thereto. The graphene channel layer 20 may have a single layer or multilayer structure.

Source and drain electrodes 30a, 30b are disposed at both ends of the graphene channel layer 20, respectively. The source and drain electrodes 30a, 30b may be electrically connected to the graphene channel layer 20. The source and drain electrodes 30a, 30b may be formed of a conductive material. In one example, the conduction material may be a metal. For example, the source and drain electrodes 30a, 30b may be composed of platinum (Pt), molybdenum (Mo), chromium (Cr), titanium (Ti), gold (Au), palladium (Pd), silver (Ag), and alloys thereof.

An insulator film 40 is disposed on the graphene channel layer 20. The insulator film 40 may be disposed on the overall surface of the graphene channel layer 20. That is, the insulator film 40 may be disposed along the surface of the graphene channel layer 20 on which the source and drain electrodes 30a, 30b are disposed. The insulator film 40 may be formed of silicon nitride (SiNₓ) or silicon oxide (SiO₂), without being limited thereto.

Gate electrodes 50 are disposed on the insulator film 40. At least two gate electrodes 50 may be disposed on the insulator film. That is, the at least two gate electrodes 50 may be disposed with a predetermined gap therebetween. In one example, the gate electrodes 50 include first and second gate electrodes 50a, 50b. Here, the first and second gate electrodes 50a, 50b may be disposed so as to overlap the source and drain electrodes 30a, 30b, respectively.

The gate electrodes 50 may be formed of a conductive material. The conductive material may be a metal. In one example, the gate electrodes 50 may have a single layer or multilayer structure including aluminum (Al), nickel (Ni), platinum (Pt), gold (Au), copper (Cu), ruthenium (Ru), cobalt (Co), palladium (Pd), or alloys thereof.

FIG. 2 shows resistance change of a graphene multiple-valued logic device according to one embodiment of the present invention.

Referring to FIG. 2, when a back gate voltage applied to the substrate 10 is taken as a reference voltage, a conduction type of the graphene channel layer 20 may be determined More particularly, depending on the applied back gate voltage, a conduction type of a third channel region 20c to which an electric field of the back gate voltage extends may be determined Here, the conduction type of the third channel region 20c may be an i-type (intrinsic type), n-type or p-type. The applied back gate voltage may be a ground voltage.

Then, with reference to the ground voltage, the conduction type of the graphene channel layer 20 may be defined by applying a positive (+) or negative (−) voltage to the first and second gate electrodes 50a, 50b. The reason is because when voltage is applied to the gate electrodes 50, an electric field formed by the applied voltage affects the graphene channel layer 20, so that a majority carrier type of the graphene channel layer 20 varies with the electric field.

In one example, when a positive (+) voltage (+V_{g}) is applied to the first gate electrode 50a, negative (−) charges may be induced in a first channel region 20a facing the first gate electrode 50a in the graphene channel layer 20. Thus, majority carriers of the first channel region 20a are electrons, and the Fermi energy level of the first channel region 20a may be moved upwards by the electrons. Therefore, the first channel region 20a may exhibit n-type conductivity.

On the other hand, when a negative (−) voltage (−V_{g}) is applied to the second gate electrode 50b, positive (−) charges may be induced in a second channel region 20b facing the second gate electrode 50b in the graphene channel layer 20. Thus, majority carriers of the second channel region 20b are holes, and the Fermi energy level of the second channel region 20b may be moved downwards by the holes. Therefore, the second channel region 20b may exhibit p-type conductivity.

In addition, the first or second channel region 20a or 20b may exhibit i-type conductivity by applying a certain voltage to the first or second gate electrode 50a, 50b. In this case, the applied voltage may be a voltage at which the Dirac point, at which the Fermi energy level is caught in the graphene channel layer 20, appears. In one example, the Dirac point of the graphene channel layer 20 may be near 0 V.

That is, the conduction type of the third channel region 20c is determined by applying the back gate voltage to the graphene channel layer 20 through the substrate 10, and a certain voltage is applied to the first and second gate electrodes 50a, 50b based on the conduction type of the third channel region, thereby defining the conduction types of the first and second channel regions 20a, 20b.

Thus, the total resistance of the graphene channel layer 20 including the channel regions 20a, 20b, 20c having the same or different conduction types may have different values depending on the back gate voltage and the gate voltage applied to the channel regions 20a, 20b, 20c. Therefore, different current levels can be exhibited in a single device.

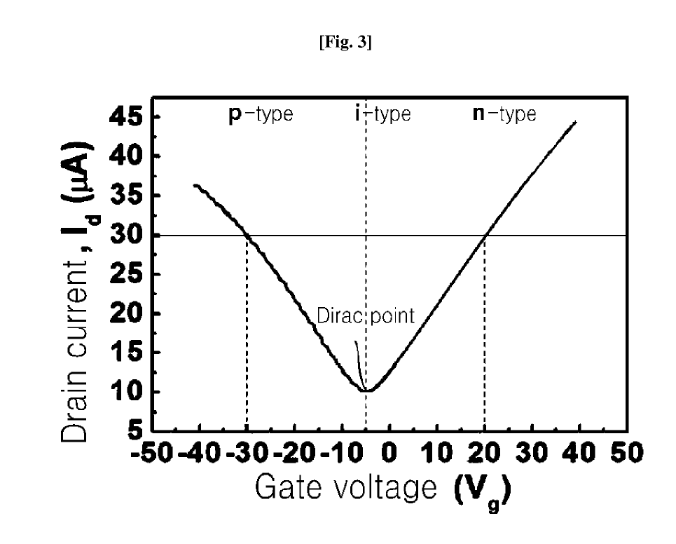

FIG. 3 shows a current-voltage characteristic curve of a graphene channel layer according to one embodiment of the present invention.

Referring FIGS. 2 and 3, a current-voltage characteristic curve may have a bilaterally symmetric curve shape with respect to the Dirac point of the graphene channel layer 20. It can be confirmed that the Dirac point of the graphene channel layer 20 exists at the gate voltage of about −5 V. Thus, if a ground voltage is applied as the back gate voltage, the graphene channel layer 20 may exhibit i-type properties. In addition, when the gate voltage of the Dirac point is taken as a reference value, if the gate voltage in a negative (−) range having larger absolute values than the reference value is applied, the graphene channel layer 20 may exhibit p-type conductivity, and if the gate voltage of a negative (−) range having smaller absolute values than the reference value and a positive (+) range is applied, the graphene channel layer 20 may exhibit n-type conductivity. The Dirac point may be another value instead of −5 V due to process change. In one example, the Dirac point may be adjusted to 0 V by process optimization.

In one example, when a resistance value at the drain current value is defined as R with reference to the gate voltage at which a drain current value is 30 μA, since the drain current value is 30 μA at gate voltage values of −30 V and +20 V, resistance values at gate voltage values of −30 V and +20 V may be defined as R.

In addition, since the drain current value at the Dirac point is 10 μA and current is inversely proportional to resistance, a resistance value at the Dirac point is larger than R. In one example, the resistance value at the Dirac point may be defined as 3R.

Thus, the resistance value of the channel regions 20a, 20b may be adjusted to 3R or R by applying −5 V, −30 V or +20 V to the first and second channel regions 20a, 20b in which the graphene channel layer 20 faces the gate electrodes 50a, 50b.

TABLE 1

| | | | Back gate | |
|---|---|---|---|---|
| | Gate Voltage | Gate Voltage | Voltage | |
| | applied to | applied to | applied to | |
| | first channel | second channel | third channel | Total |
| Case | region 20a | region 20b | region 20c | resistance |
| 1 | +20 V | +20 V | 0 V | R + R + 3R = 5R |
| 2 | +20 V | −30 V | | R + R + 3R = 5R |
| 3 | +20 V | −5 V | | R + 3R + 3R = 7R |
| 4 | −30 V | +20 V | | R + R + 3R = 5R |
| 5 | −30 V | −30 V | | R + R + 3R = 5R |
| 6 | −30 V | −5 V | | R + 3R + 3R = 7R |
| 7 | −5 V | +20 V | | 3R + R + 3R = 7R |
| 8 | −5 V | −30 V | | 3R + R + 3R = 5R |
| 9 | −5 V | −5 V | | 3R + 3R + 3R = 9R |

Table 1 shows calculated results of the total resistance of the graphene channel layer 20 after applying −5 V, −30 V or +20 V to the first or second gate electrode 50a, 50b.

As shown in Table 1, depending on voltage applied to the gate electrodes 50, the graphene channel layer 20 may have 3 types of resistance values of 3R, 5R and 7R, and may also have 3 types of drain current values depending on differences of the resistance values. That is, since the device in FIG. 2 may have 3 current levels, a multiple-valued logic for ternary notation may be realized using the same.

Although FIG. 3 illustrates one example in which the current-voltage characteristic curve has the bilaterally symmetric curve shape with respect to the Dirac point of the graphene channel layer 20, the current-voltage characteristic curve may have a bilaterally asymmetric curve shape with respect to the Dirac point of the graphene channel layer 20. In this case, since the resistance due to the gate voltage applied to the first gate electrode 50a differs from the resistance due to the gate voltage applied to the second gate electrode 50b, there are a more number of cases of the resistance values of the graphene channel layer 20 than in the bilaterally symmetric case. Thus, since the device in this case has 3 or more drain current values, the device may have 3 or more current levels.

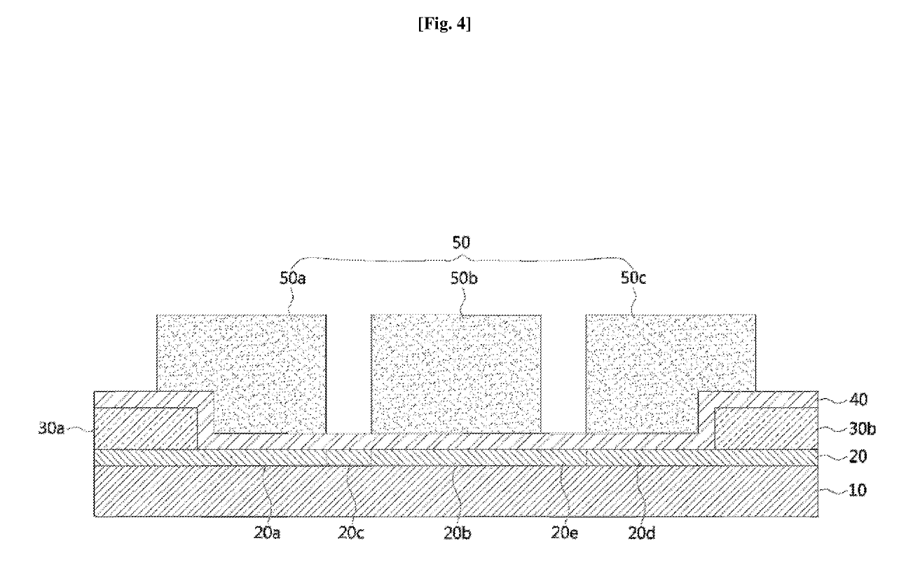

FIG. 4 is a sectional view of a graphene multiple-valued logic device according to another embodiment of the present invention.

Referring to FIG. 4, the graphene multiple-valued logic device according to this embodiment includes: a graphene channel layer 20 disposed on a substrate 10; source and drain electrodes 30a, 30b disposed at both ends of the graphene channel layer 20, respectively; an insulator film 40 formed on the graphene channel layer 20; and gate electrodes 50 disposed on the insulator film 40 with a predetermined gap defined therebetween.

In this embodiment, three gate electrodes 50 may be disposed on the insulator film 40. Specifically, the gate electrodes 50 may include first, second and third gate electrodes 50a, 50b, 50c. Here, the first and third gate electrodes 50a, 50c may be disposed so as to overlap the source and drain electrodes 30a, 30b, respectively.

Conduction types of third and fifth channel regions 20c, 20e are determined by applying a back gate voltage to the graphene channel layer 20 through the substrate 10, and a certain voltage is applied to the first, second and third gate electrodes 50a, 50b, 50c according to the determined conduction types, thereby defining the conduction types of the first, second and fourth channel regions 20a, 20b, 20d.

More particularly, ground voltage may be applied as back gate voltage to the third channel region 20c in the graphene channel layer 20 facing a region between the first and second gate electrodes 50a, 50b, and to the fifth channel region 20e facing a region between the second and third gate electrodes 50b, 50c. Here, the third and fifth channel regions 20c, 20e may exhibit i-type, p-type or n-type conductivity.

Then, with reference to the ground voltage, voltage to be applied to the first, second and third gate electrodes 50a, 50b, 50c is determined and the conduction types of the first, second and fourth channel regions 20a, 20b, 20d may be defined by applying the voltage thereto.

Thus, the total resistance of the graphene channel layer 20 including the channel regions 20a, 20b, 20c, 20d, 20e having the same or different conduction types may have different values depending on the back gate voltage and the gate voltage applied to the channel regions 20a, 20b, 20c, 20d, 20e. Therefore, different current levels can be exhibited in a single device.

Since other components are the same as the device in FIG. 1, a detailed description thereof will be omitted.

As described above, the three gate electrodes 50 are disposed on the insulator film and the gate voltage applied to each of the gate electrodes 50 is adjusted, thereby changing the conduction type of each of the channel regions 20a, 20b, 20c, 20d, 20e in the graphene channel layer 20. Thus, the total resistance of the graphene channel layer 20 can be controlled.

In addition, the resistance of the graphene channel layer 20 can be more finely controlled than the device having two gate electrodes 50, and the device having three gate electrodes 50 can exhibit more diverse current levels.

Although three gate electrodes 50 are illustrated in FIG. 4, the number of gate electrodes 50 is not limited thereto, and more gate electrodes 50 may be disposed on the insulator film 40, as needed.

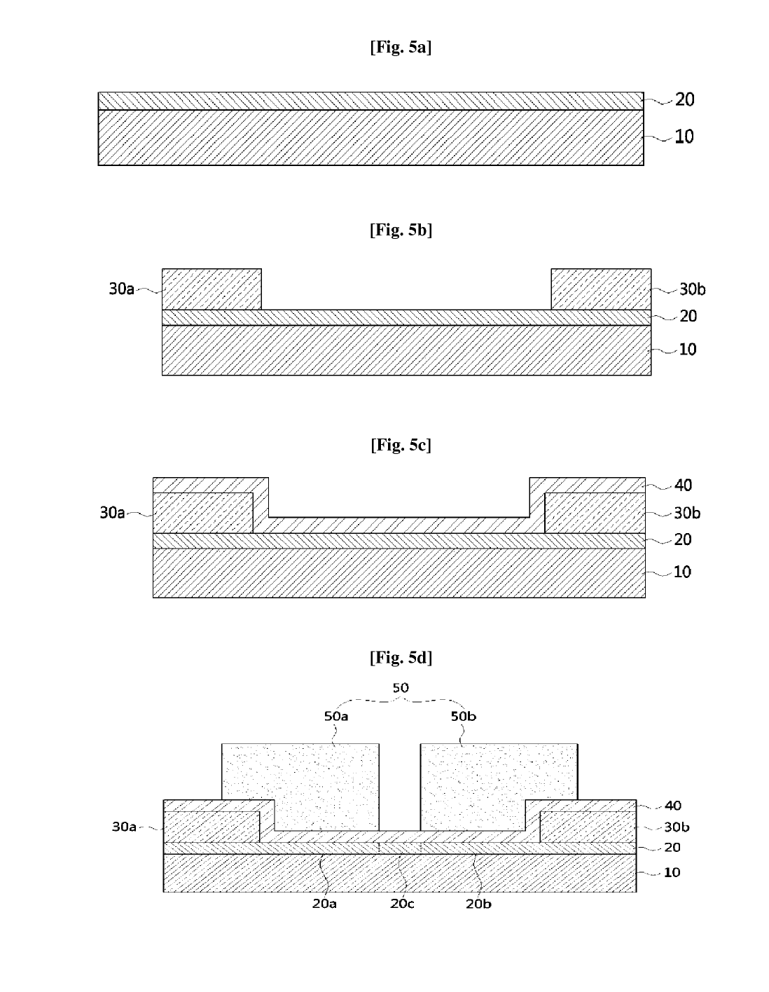

FIGS. 5a to 5d show flow diagrams of a method of fabricating a graphene multiple-valued logic device according to one embodiment of the present invention.

Referring to FIG. 5a, a graphene channel layer 20 is formed on a substrate 10. The substrate 10 may be a silicon substrate coated with a silicon oxide film (SiO₂). The graphene channel layer 20 may be formed as a single layer or multiple layers.

In one example, the graphene channel layer 20 may be formed by transferring a graphene sheet grown on a sacrificial substrate (not shown) onto the substrate 10. Here, the graphene sheet may be formed on the sacrificial substrate using a method known to those skilled in the art, such as mechanical exfoliation, chemical exfoliation, chemical vapor deposition, epitaxial synthesis, organic synthesis, and the like.

Referring to FIG. 5b, source and drain electrodes 30a, 30b are formed at both ends of the graphene channel layer 20. The source and drain electrodes 30a, 30b may be formed of a conductive material. The conductive material may be a metal.

In one example, after deposition of an electrode material, the source and drain electrodes 30a, 30b may be formed by patterning the electrode material. Deposition may be performed using thermal evaporation, sputtering, chemical vapor deposition, and the like. Patterning may be achieved through typical lithography and etching.

Referring to FIG. 5c, an insulator film 40 is formed on the graphene channel layer 20. The insulator film 40 may be formed on the overall surface of the graphene channel layer 20. That is, the insulator film 40 may be formed along the surface of the graphene channel layer 20 on which the source and drain electrodes 30a, 30b are disposed.

The insulator film 40 may be formed by sputtering, plasma enhanced chemical vapor deposition or atomic layer deposition, without being limited thereto, and may be formed using a typical deposition process.

Referring to FIG. 5d, gate electrodes 50 are formed on the insulator film 40. At least two electrodes 50 may be formed thereon. Here, the at least one of the gate electrodes 50 may be formed so as to overlap the source or drain electrode 30a, 30b, respectively. The gate electrodes 50 may be formed of a conductive material. The conductive material may be a metal.

After deposition of an electrode material, the gate electrodes 50 may be formed by patterning the electrode material. Deposition may be performed using thermal evaporation, sputtering, chemical vapor deposition, or the like. Patterning may be achieved through typical lithography and etching.

Although the present invention has been described with reference to some embodiments in conjunction with the accompanying drawings, it should be understood that the present invention is not limited to the foregoing embodiments, and that various modifications, changes, alterations, and equivalent embodiments can be made by those skilled in the art without departing from the spirit and scope of the invention.

What is claimed is:

1. A graphene multiple-valued logic device comprising:
a substrate;
a graphene channel layer disposed on the substrate;
source and drain electrodes disposed at both ends of the graphene channel layer, respectively;
an insulator film formed on the graphene channel layer; and
at least two gate electrodes disposed on the insulator film with a predetermined gap defined therebetween.

2. The device according to claim 1, wherein a ground voltage is applied to a region in the graphene channel layer facing the predetermined gap between the gate electrodes through the substrate.

3. The device according to claim 1, wherein the graphene channel layer has one selected from among p-type, n-type and i-type conductivities in a region facing the gate electrodes depending on voltage applied to the gate electrodes.

4. The device according to claim 1, wherein the source and drain electrodes overlap at least one of the gate electrodes.

5. A method of operating a graphene multiple-valued logic device comprising:
providing a graphene multiple-valued logic device, the graphene multiple-valued logic device comprising: a substrate; a graphene channel layer disposed on the substrate; source and drain electrodes disposed at both ends of the graphene channel layer, respectively; an insulator film formed on the graphene channel layer on which the source and drain electrodes are disposed; and first and second gate electrodes disposed on the insulator film with a predetermined gap defined therebetween;
determining a conduction type of the graphene channel layer by applying a ground voltage to the graphene channel layer disposed between the first and second gate electrodes;
forming a conduction type of the graphene channel layer facing the first gate electrode by applying a positive or negative gate voltage to the first gate electrode with reference to the ground voltage;
forming a conduction type of the graphene channel layer facing the second gate electrode by applying a positive or negative gate voltage to the second gate electrode with reference to the ground voltage; and
calculating total resistance of the graphene channel layer varying with voltage applied to the first and second gate electrodes.

6. The method according to claim 5, wherein the determining a conduction type of the graphene channel layer is an operation of applying a back gate voltage to the graphene channel layer using the substrate as a back gate.

7. The method according to claim 5, wherein each of a region of the graphene channel layer facing the first gate electrode and a region of the graphene channel layer facing the second gate electrode has one conduction type selected from among p-type, n-type and i-type conductivities.

8. A method of fabricating a graphene multiple-valued logic device comprising:
forming a graphene channel layer on a substrate;
forming source and drain electrodes at both ends of the graphene channel, respectively;
forming an insulator film on the graphene channel layer on which the source and drain electrodes are formed; and
forming at least two gate electrodes on the insulator film.

9. The method according to claim 8, wherein the gate electrodes are disposed to have a predetermined gap therebetween.

10. The method according to claim 8, further comprising: forming regions each having one conduction type selected from among p-type, n-type and i-type conductivities within the graphine channel layer facing the gate electrodes by applying voltage to the gate electrodes.
